(19) United States
(12) Patent Application Publication
(10) Pub. No.: US 2012/0319149 A1
(43) Pub. Date: Dec. 20, 2012

(54) Light-Emitting Device Structure and Method for Manufacturing the Same

(75) Inventors: Yan-Kuin Su, Tainan (TW); Kuan-Chun Chen, Taichung City (TW); Chun-Liang Lin, Tainan City (TW)

(73) Assignee: NATIONAL CHENG KUNG UNIVERSITY, Tainan City (TW)

(21) Appl. No.: 13/230,917

(22) Filed: Sep. 13, 2011

(30) Foreign Application Priority Data
Jun. 17, 2011 (TW) 100121250

(51) Int. Cl. H01L 33/58; H01L 33/48

(52) U.S. Cl. 257/98; 438/33; 257/E33.074; 257/E33.056

(57) ABSTRACT

A light-emitting device structure and a method for manufacturing the same are described. The light-emitting device structure includes a substrate and an illuminant structure. The substrate has a top surface and a lower surface on opposite sides, and two inclined side surfaces on opposite sides. Two sides of each inclined side surface are respectively connected to the top surface and the lower surface. The illuminant structure is disposed on the top surface.

### RELATED APPLICATIONS

This application claims priority to Taiwan Application Serial Number 100121250, filed Jun. 17, 2011, which is herein incorporated by reference.

### FIELD OF THE INVENTION

The present invention relates to a light-emitting structure, and more particularly to a light-emitting device structure and a method for manufacturing the same.

### BACKGROUND OF THE INVENTION

Currently, a dicing procedure of a light-emitting diode (LED) chip is performed by firstly scribing on a surface of a wafer with a single beam laser and then splitting the wafer. FIG. 1A through FIG. 1C are schematic flow diagrams showing a method for manufacturing a conventional light-emitting device structure. Typically, in the fabrication of a light-emitting device structure, a main substrate 100 is firstly provided. The main substrate 100 includes two surfaces 102 and 104 on opposite sides.

As shown in FIG. 1A, a plurality of illuminant structures 106a and 106b are disposed on the surface 102 of the main substrate 100. Each of the illuminant structures 106a and 106b includes an epitaxial structure 108, a transparent electrically conductive layer 110, a first electrode 112 and a second electrode 114. The transparent electrically conductive layer 110 covers a portion of the epitaxial structure 108, the first electrode 112 is disposed on another portion of the epitaxial structure 108, and the second electrode 114 is disposed on a portion of the transparent electrically conductive layer 110.

As shown in FIG. 1A, a single beam laser 116 is focused on the surface 102 of the main substrate 100 and is used to scribe the surface 102 of the main substrate 116 between the adjacent illuminant structures 106a and 106b. After scribing, as shown in FIG. 1B, scribing regions 118 are formed on the surface 102 of the main substrate 100.

Next, the main substrate 100 is split along the scribing regions 118 to divide the main substrate 100 into a plurality of substrates 122. Accordingly, the illuminant structures 106a and 106b respectively located on the substrates 122 can be separated to substantially complete a light-emitting device structure 120, as shown in FIG. 1C.

The aforementioned scribing treatment is performed on the front of the main substrate. However, the scribing treatment of the main substrate may be performed on the rear of the main substrate. FIG. 2A through FIG. 2C are schematic flow diagrams showing a method for manufacturing another conventional light-emitting device structure. In the conventional process, after a plurality of illuminant structures 106a and 106b are disposed on a surface 102 of a main substrate 100, the main substrate 100 and the illuminant structures 106a and 106b thereon are reversed to turn a surface 104 of the main substrate 100 upward.

As shown in FIG. 2A, a single beam laser 116 is focused on the surface 104 of the main substrate 100 and is used to scribe the surface 104 of the main substrate 116 between the adjacent illuminant structures 106a and 106b. After scribing, as shown in FIG. 2B, scribing regions 118 are formed on the surface 104 of the main substrate 100.

Next, the main substrate 100 is split along the scribing regions 118 to divide the main substrate 100 into a plurality of substrates 122, thereby separating the adjacent illuminant structures 106a and 106b respectively located on the substrates 122. As shown in FIG. 2C, a light-emitting device structure 120 is substantially completed.

FIG. 3 is a schematic diagram showing a light path in a substrate of a conventional light-emitting device structure. The single beam laser only can be focused on the front or the rear of the main substrate 100 to perform the scribing treatment of the surface of the main substrate 100, so that an inclined side surface, which is beneficial for light extraction, is difficult to form on the substrate. Therefore, in the aforementioned method including the steps of using the single beam laser to scribe the main substrate and then splitting the main substrate, a side surface 126 of the substrate 122 formed after splitting is a nearly vertical surface. As a result, light 124 emitted by the illuminant structure 106a toward the underlying substrate 122 will be totally reflected by the vertical side surface 126 easily. Accordingly, the light-extracted intensity of the light-emitting device structure 120 is reduced.

Using a grinding wheel and a mechanical cutter to directly dice a main substrate of a light-emitting device also can form a substrate including a side surface with a specific inclination angle. However, the attrition of the grinding wheel and the mechanical cutter is very significant, and the dicing rate is slow, so that the cost is greatly increased and the throughput is less, thereby being disadvantageous for mass production.

### SUMMARY OF THE INVENTION

One aspect of the present invention is to provide a light-emitting device structure and a method for manufacturing the same, in which a multiple beam laser is used to dice a main substrate. Therefore, a light-emitting device structure including a substrate having inclined side surfaces can be successfully made to increase the light-extracting efficiency of the substrate of the light-emitting device structure.

Another aspect of the present invention is to provide a light-emitting device structure and a method for manufacturing the same, in which a substrate having inclined side surfaces can be successfully formed without using a grinding wheel and a cutter, so that the dicing rate of the light-emitting device structures is increased to effectively decrease the fabrication cost, thereby benefiting the mass production.

According to the aforementioned aspects, the present invention provides a light-emitting device structure. The light-emitting device structure includes a substrate and an illuminant structure. The substrate has a top surface and a lower surface on opposite sides, and two inclined side surfaces on opposite sides. Two sides of each inclined side surface are respectively connected to the top surface and the lower surface. The illuminant structure is disposed on the top surface.

According to a preferred embodiment of the present invention, an inclined angle of each inclined side surface ranges from 0.5 degree to 89.5 degrees.

According to another preferred embodiment of the present invention, a width of the substrate is gradually increased from the top surface to the lower surface.

According to still another preferred embodiment of the present invention, a width of the substrate is gradually decreased from the top surface to the lower surface.

According to the aforementioned aspects, the present invention further provides a method for manufacturing a light-emitting device structure, which includes the following steps. A main substrate is provided, in which the main substrate has a top surface and a lower surface on opposite sides. A plurality of illuminant structures are formed on the top surface. A dicing treatment is performed on the main substrate between the adjacent illuminant structures by a plurality of laser beams to form a trench in the main substrate between the adjacent illuminant structures respectively. A splitting step is performed to split the main substrate along the trenches to form a plurality of light-emitting device structures, in which each light-emitting device structure includes a substrate formed by dicing the main substrate, and each substrate has two inclined side surfaces on opposite sides.

According to a preferred embodiment of the present invention, a pitch of the laser beams ranges from 0.1 μm to 100 mm.

According to another preferred embodiment of the present invention, energy of each laser beam ranges from 1 μW to 100 W.

According to still another preferred embodiment of the present invention, a focus depth of each laser beam ranges from 0.1 nm to 10 mm.

According to further another preferred embodiment of the present invention, each trench is U-shaped or V-shaped.

According to yet another preferred embodiment of the present invention, the dicing treatment is performed on the top surface of the main substrate.

According to still further another preferred embodiment of the present invention, the dicing treatment is performed on the lower surface of the main substrate.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1A through FIG. 1C are schematic flow diagrams showing a method for manufacturing a conventional light-emitting device structure;

FIG. 2A through FIG. 2C are schematic flow diagrams showing a method for manufacturing another conventional light-emitting device structure;

FIG. 3 is a schematic diagram showing a light path in a substrate of a conventional light-emitting device structure;

FIG. 4A through FIG. 4C are schematic flow diagrams showing a method for manufacturing a light-emitting device structure in accordance with an embodiment of the present invention; and

FIG. 5A through FIG. 5C are schematic flow diagrams showing a method for manufacturing a light-emitting device structure in accordance with another embodiment of the present invention.

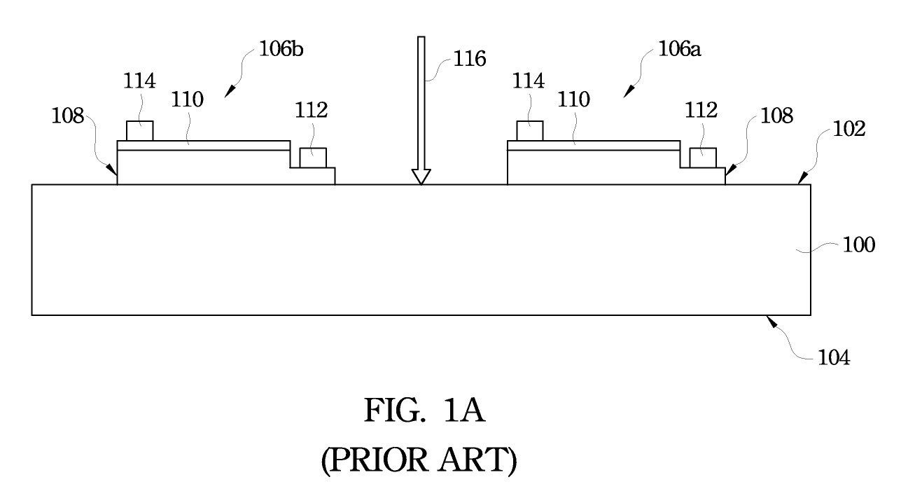

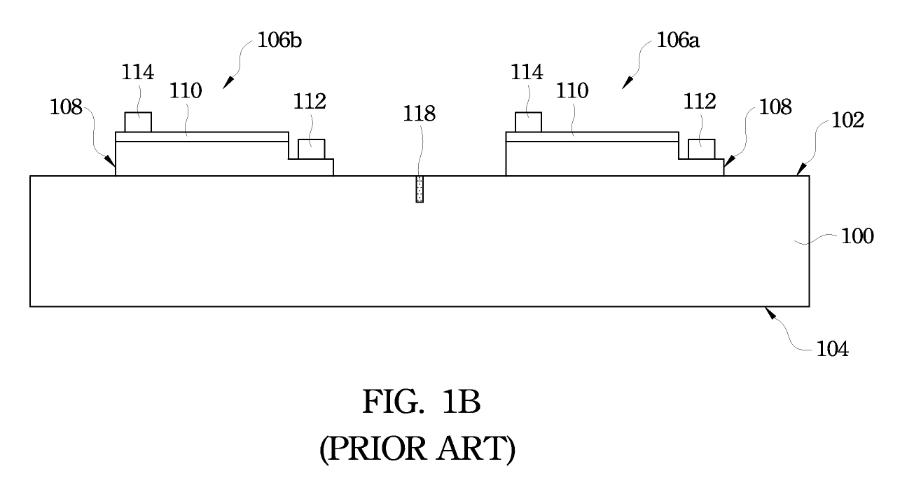

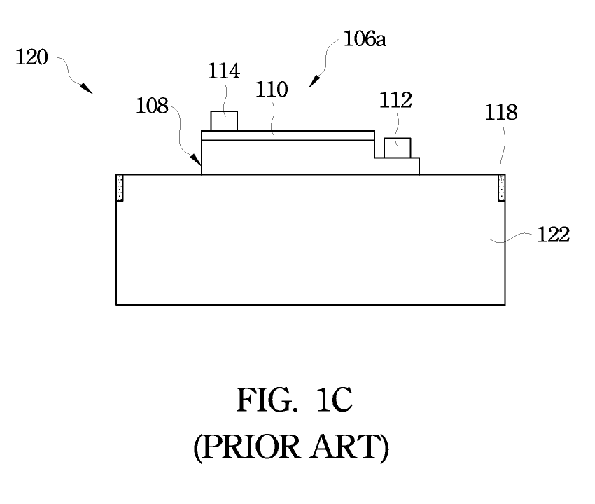

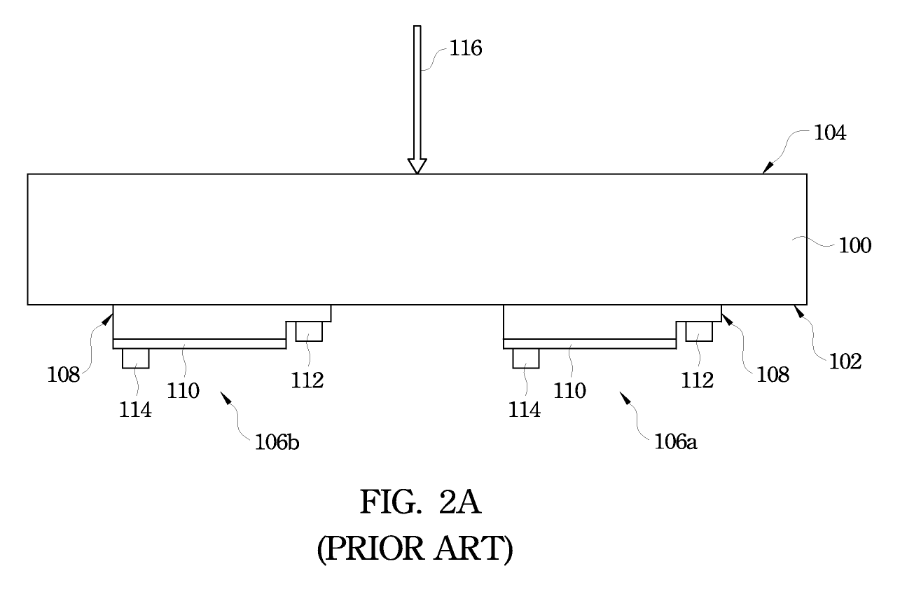

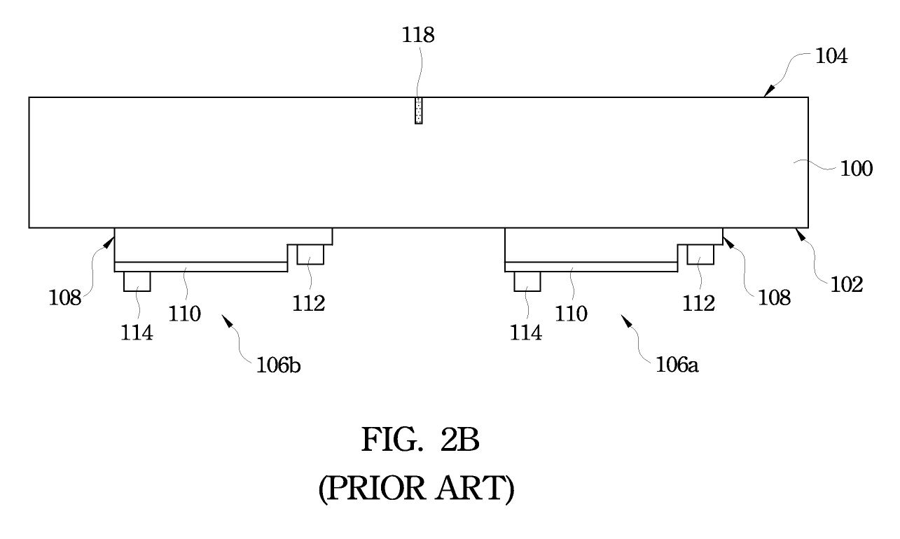

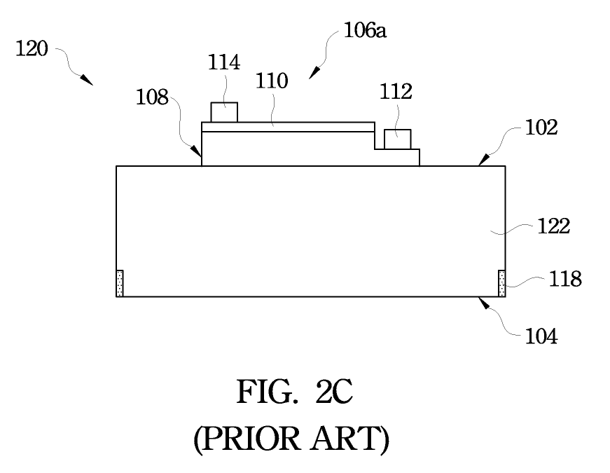

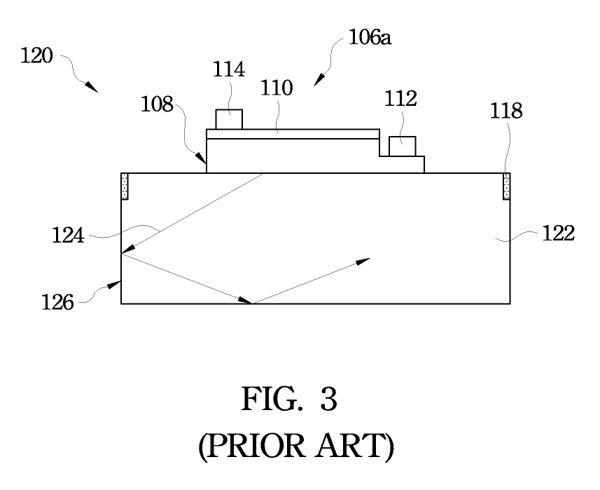

### DETAILED DESCRIPTION OF THE PREFERRED EMBODIMENT

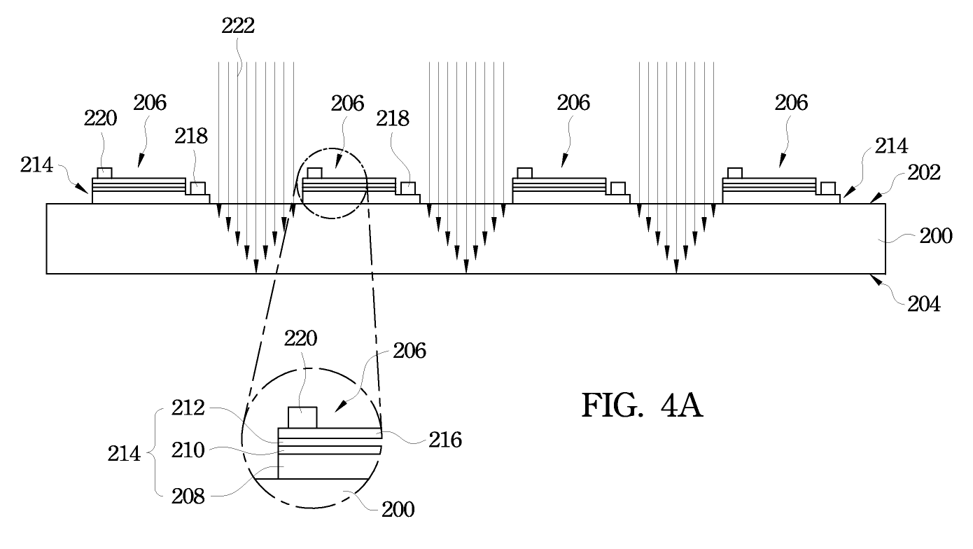

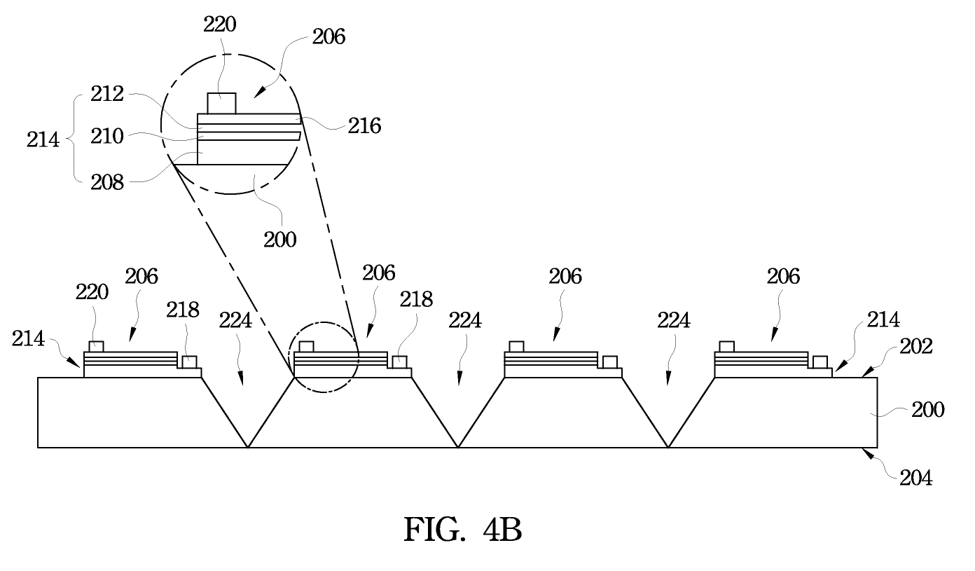

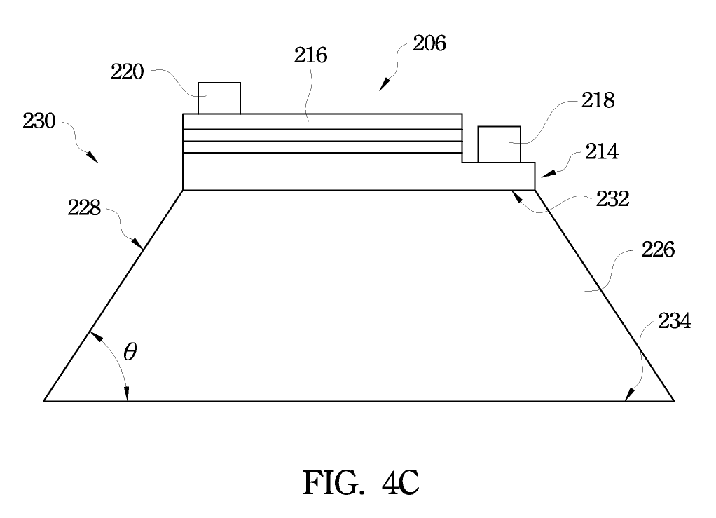

FIG. 4A through FIG. 4C are schematic flow diagrams showing a method for manufacturing a light-emitting device structure in accordance with an embodiment of the present invention. In the present embodiment, in the manufacture of a light-emitting device structure 230 shown in FIG. 4C, a main substrate 200 is provided. The light-emitting device structure 230 is a light-emitting diode (LED) device, for example. The main substrate 200 may be a wafer. The main substrate 200 may be a growth substrate used in an epitaxy process, or may be a bonding substrate bonding with an epitaxial structure 214 by a wafer bonding method after the epitaxial structure is formed. The main substrate 200 has a top surface 202 and a lower surface 204 on opposite sides.

Next, a plurality of illuminant structures 206 are formed on the top surface 202 of the main substrate 200. In one embodiment, the illuminant structure 206 may include the epitaxial structure 214 and two electrodes 218 and 220. In another embodiment, the illuminant structure 206 may further include a transparent electrically conductive layer 216 selectively. The transparent electrically conductive layer 216 is disposed between the epitaxial structure 214 and the electrode 220 to spread the current input into the illuminant structure 206.

Referring to FIG. 4A, the illuminant structure 206 is a lateral conducting type structure in an exemplary embodiment. The epitaxial structure 214 includes a first conductivity type semiconductor layer 208, an active layer 210 and a second conductivity type semiconductor layer 212. The first conductivity type semiconductor layer 208 is disposed on the top surface 202 of the main substrate 200, the active layer 210 is disposed on a portion of the first conductivity type semiconductor layer 208, and the second conductivity type semiconductor layer 212 is disposed on the active layer 210. The transparent electrically conductive layer 216 is disposed on the second conductivity type semiconductor layer 212, the electrode 220 is disposed on the transparent electrically conductive layer 216, and the electrode 218 is disposed on another portion of the first conductivity type semiconductor layer 208. The first conductivity type and the second conductivity type are different conductivity types. For example, when one of the first conductivity type and the second conductivity type is n-type, the other one of the first conductivity type and the conductivity type is p-type.

In another embodiment, the illuminant structure may be a vertical conducting type structure, i.e. two electrodes of the illuminant structure are respectively disposed on opposite sides of the illuminant structure.

Next, as shown in FIG. 4A, a plurality of laser beams 222 are focused on the top surface 202 of the main substrate 200 between any adjacent two of the illuminant structures 206 to perform a dicing treatment on the top surface 202 of the main substrate 200 between the adjacent illuminant structures 206 by the laser beams 222. The laser beams 222 may be provided by a single-pulse laser having at least two light beams, i.e. the pulse laser is a multiple beam laser. As shown in FIG. 4B, after the dicing treatment is performed by the laser beams 222, trenches 224 are respectively formed in the top surface 202 of the main substrate 200 between any two adjacent illuminant structures 206.

The trenches 224 in any shapes can be formed in the main substrate 200 between the adjacent illuminant structures 206 by simultaneously controlling pitches, energy and focus depths of the laser beams 222. In some embodiments, the trenches 224 may be U-shaped or V-shaped. The pitch of the laser beams 222, and the energy and the focus depth of each laser beam 222 may be adjusted according to process requirements. In some embodiments, the pitch of the laser beams 222 may range from 0.1 μm to 100 mm; the energy of each laser beam 222 may range from 1 μW to 100 W; and the focus depth of each laser beam 222 may range from 0.1 nm to 10 mm. In other embodiments, the laser beams 222 may pass through the main substrate 200, or may not pass through the main substrate 200. In addition, according to the process requirements, the dicing treatment may pass through the main substrate 200, or may not pass through the main substrate 200.

Then, a splitting step is performed on the main substrate 200 by a mechanical method, such as cleaving or expanding, to divide the main substrate 200 into a plurality of substrates 226 along the trenches 224 in the top surface 202 of the main substrate 200. As a result, a plurality of light-emitting device structures 230 are formed. Each light-emitting device structure 230 includes the substrate 226 divided from the main substrate 200 and the illuminant structure 206 on a top surface 232 of the substrate 226, as shown in FIG. 4C.

The trenches 224 are formed in the top surface 202 of the main substrate 200 between the adjacent illuminant structures 206 by the laser beams 222 in the previous dicing treatment, so that the substrate 226 formed by splitting the main substrate 200 at least includes two inclined side surfaces 228 on opposite sides. Two sides of each inclined side surface 228 of the substrate 226 are respectively connected to a top surface 232 and an opposite lower surface 234 of the substrate 226. In some embodiments, an inclined angle θ of the inclined side surface 228 ranges from 0.5 degree to 89.5 degrees, for example.

In one embodiment, each laser beam 222 forms a hole or a ragged structure at a focus of the laser beam 222 or a region adjacent to the focus in the main substrate 200, so that the trench 224 has a rough surface. Accordingly, the inclined side surface 228 of the substrate 226 formed by splitting the main substrate 200 along the trench 224 has the rough surface formed by dicing the main substrate 200 through the laser beams 222. Light emitted by the illuminant structure 206 toward the substrate 226 can be successfully extracted from the rough inclined side surfaces 228, thereby increasing the light extraction efficiency of the light-emitting device structure 230.

In the light-emitting device structure 230, a width of the substrate 226 is gradually increased from the top surface 232 to the lower surface 234. In addition, a side view of the substrate 226 may be in a trapezoid, for example.

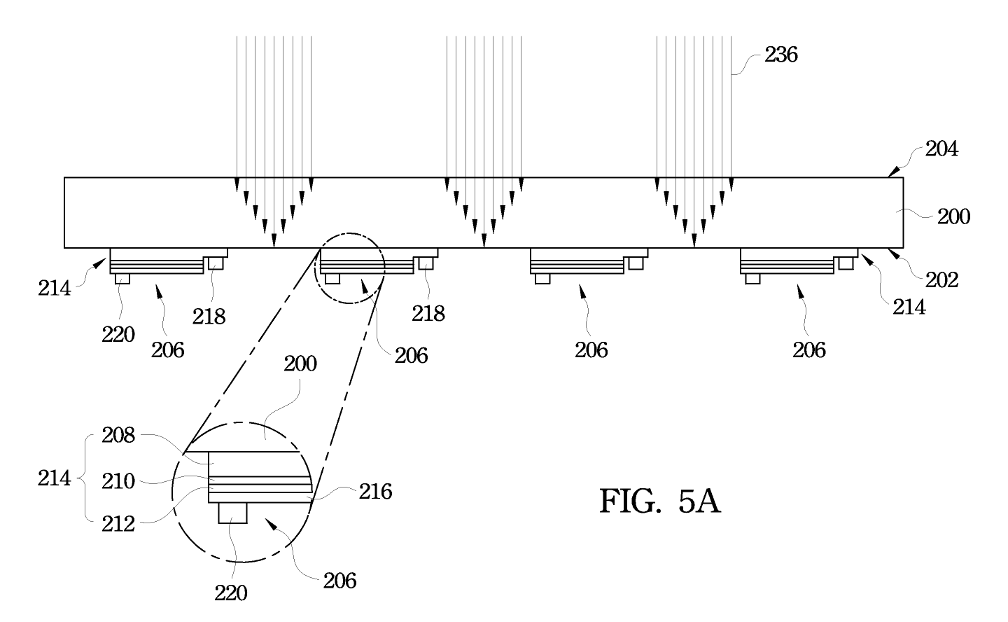

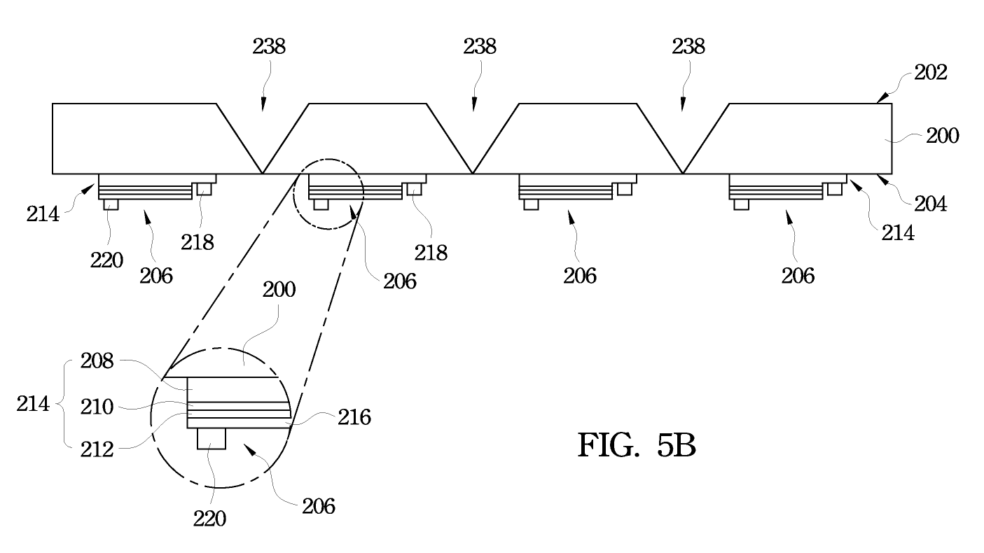

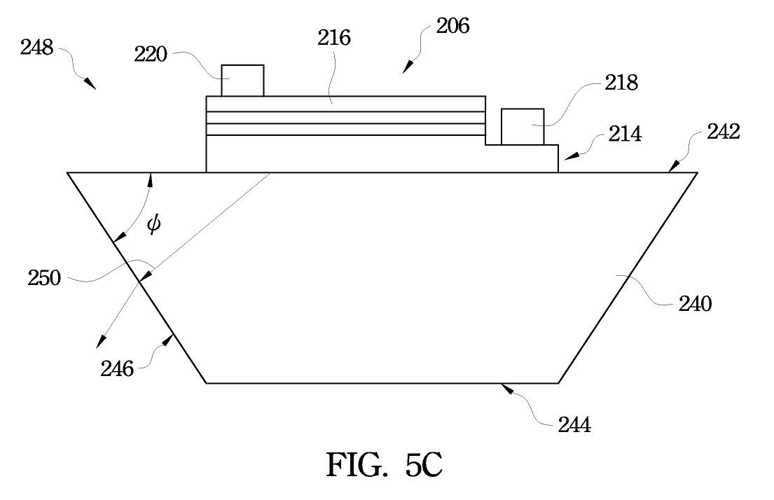

The laser dicing treatment in the aforementioned embodiment is performed by a front dicing method, and the laser dicing treatment of the present invention also can use a rear dicing method. FIG. 5A through FIG. 5C are schematic flow diagrams showing a method for manufacturing a light-emitting device structure in accordance with another embodiment of the present invention. In the present embodiment, in the manufacture of a light-emitting device structure 248 shown in FIG. 5C, a plurality of illuminant structures 206 are formed on a top surface 202 of a main substrate 200 similarly. Then, the main substrate 200 and the illuminant structures 206 on its top surface 202 are reversed to turn a lower surface 204 of the main substrate 200 upward.

Then, as shown in FIG. 5A, a plurality of laser beams 236 are focused on the lower surface 204 of the main substrate 200 between any adjacent two of the illuminant structures 206 to perform a dicing treatment on the lower surface 204 of the main substrate 200 between the adjacent illuminant structures 206 by the laser beams 236. As shown in FIG. 5B, after the dicing treatment is performed by the laser beams 236, trenches 238 are respectively formed in the lower surface 204 of the main substrate 200 between any two adjacent illuminant structures 206.

Similarly, the trenches 238 in any shapes can be formed in the main substrate 200 between the adjacent illuminant structures 206 by simultaneously controlling pitches, energy and focus depths of the laser beams 236. In some embodiments, the trenches 238 may be U-shaped or V-shaped. The pitch of the laser beams 236, and the energy and the focus depth of each laser beam 236 may be adjusted according to process requirements. In some embodiments, the pitch of the laser beams 236 may range from 0.1 μm to 100 mm; the energy of each laser beam 236 may range from 1 μW to 100 W; and the focus depth of each laser beam 236 may range from 0.1 nm to 10 mm. In addition, according to the process requirements, the dicing treatment may pass through the main substrate 200, or may not pass through the main substrate 200.

Then, a splitting step is performed on the main substrate 200 by a mechanical method, such as cleaving or expanding, to divide the main substrate 200 into a plurality of substrates 240 along the trenches 238 in the lower surface 204 of the main substrate 200. As a result, a plurality of light-emitting device structures 248 are formed. Each light-emitting device structure 248 includes the substrate 240 divided from the main substrate 200 and the illuminant structure 206 on a top surface 242 of the substrate 240, as shown in FIG. 5C.

The trenches 238 are formed in the lower surface 204 of the main substrate 200 between the adjacent illuminant structures 206 by the laser beams 236 in the previous dicing treatment, so that the substrate 240 formed by splitting the main substrate 200 at least includes two inclined side surfaces 246 on opposite sides. Similarly, two sides of each inclined side surface 246 of the substrate 240 are respectively connected to a top surface 242 and an opposite lower surface 244 of the substrate 240. In some embodiments, an inclined angle φ of the inclined side surface 240 ranges from 0.5 degree to 89.5 degrees, for example.

In the light-emitting device structure 248, a width of the substrate 240 is gradually decreased from the top surface 242 to the lower surface 244. In addition, a side view of the substrate 240 may be in a trapezoid, for example.

As shown in FIG. 5C, the substrate 240 of the light-emitting device structure 248 includes the inclined side surfaces 246, so that light emitted by the illuminant structure 206 can be successfully extracted from the inclined side surfaces 246 without being totally reflected. Accordingly, the light-extracted intensity of the light-emitting device structure 248 is greatly increased.

According to the aforementioned embodiments, one advantage of the present invention is that a multiple beam laser is used to dice a main substrate, so that a light-emitting device structure including a substrate having inclined side surfaces can be successfully made to increase the light-extracting efficiency of the substrate of the light-emitting device structure.

According to the aforementioned embodiments, another advantage of the present invention is that a substrate having inclined side surfaces can be successfully formed without using a grinding wheel and a cutter, so that the dicing rate of a light-emitting device structures is increased to effectively decrease the fabrication cost, thereby benefiting the mass production.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A light-emitting device structure, includes:
a substrate having a top surface and a lower surface on opposite sides, and two inclined side surfaces on opposite sides, wherein two sides of each of the inclined side surfaces are respectively connected to the top surface and the lower surface; and
an illuminant structure disposed on the top surface.

2. The light-emitting device structure according to claim 1, wherein an inclined angle of each of the inclined side surfaces ranges from 0.5 degree to 89.5 degrees.

3. The light-emitting device structure according to claim 1, wherein a width of the substrate is gradually increased from the top surface to the lower surface.

4. The light-emitting device structure according to claim 1, wherein a width of the substrate is gradually decreased from the top surface to the lower surface.

5. The light-emitting device structure according to claim 1, wherein the light-emitting device structure is a light-emitting diode.

6. The light-emitting device structure according to claim 1, wherein each of the inclined side surfaces is a rough surface.

7. A method for manufacturing a light-emitting device structure, including:
providing a main substrate, wherein the main substrate has a top surface and a lower surface on opposite sides;
forming a plurality of illuminant structures on the top surface;
performing a dicing treatment on the main substrate between the adjacent illuminant structures by a plurality of laser beams to form a trench in the main substrate between the adjacent illuminant structures respectively; and
performing a splitting step to split the main substrate along the trenches to form a plurality of light-emitting device structures, wherein each of the light-emitting device structures includes a substrate formed by dicing the main substrate, and each of the substrates has two inclined side surfaces on opposite sides.

8. The method for manufacturing a light-emitting device structure according to claim 7, wherein a pitch of the laser beams ranges from 0.1 μm to 100 mm.

9. The method for manufacturing a light-emitting device structure according to claim 7, wherein energy of each of the laser beams ranges from 1 μW to 100 W.

10. The method for manufacturing a light-emitting device structure according to claim 7, wherein a focus depth of each of the laser beams ranges from 0.1 nm to 10 mm.

11. The method for manufacturing a light-emitting device structure according to claim 7, wherein each of the trenches is U-shaped.

12. The method for manufacturing a light-emitting device structure according to claim 7, wherein each of the trenches is V-shaped.

13. The method for manufacturing a light-emitting device structure according to claim 7, wherein an inclined angle of each of the inclined side surfaces ranges from 0.5 degree to 89.5 degrees.

14. The method for manufacturing a light-emitting device structure according to claim 7, wherein each of the substrates has a top surface and a lower surface on opposite sides, and a width of each of the substrates is gradually increased from the top surface to the lower surface of the substrate.

15. The method for manufacturing a light-emitting device structure according to claim 7, wherein each of the substrates has a top surface and a lower surface on opposite sides, and a width of each of the substrates is gradually decreased from the top surface to the lower surface of the substrate.

16. The method for manufacturing a light-emitting device structure according to claim 7, wherein the dicing treatment is performed on the top surface of the main substrate.

17. The method for manufacturing a light-emitting device structure according to claim 7, wherein the dicing treatment is performed on the lower surface of the main substrate.

18. The method for manufacturing a light-emitting device structure according to claim 7, wherein each of the laser beams passes through the main substrate.

19. The method for manufacturing a light-emitting device structure according to claim 7, wherein each of the laser beams does not pass through the main substrate.

20. The method for manufacturing a light-emitting device structure according to claim 7, wherein each of the laser beams forms a hole or a ragged structure at a focus of the laser beam or a region adjacent to the focus in the main substrate during the dicing treatment.
